(19) United States
(12) Patent Application Publication
(10) Pub. No.: US 2026/0114319 A1
(43) Pub. Date: Apr. 23, 2026

(54) Semiconductor Device

(71) Applicant: QUANZHOU SANAN INTEGRATED CIRCUIT CO., LTD., Quanzhou (CN)

(72) Inventors: Kai Chen, Quanzhou (CN); Huiqiang Gao, Quanzhou (CN); Jianming Yu, Quanzhou (CN); Zhicheng Huang, Quanzhou (CN); Wei Huang, Quanzhou (CN)

(21) Appl. No.: 19/360,649

(22) Filed: Oct. 16, 2025

(30) Foreign Application Priority Data
Oct. 18, 2024 (CN) 202411463135.1

(51) Int. Cl. H01L 23/10; H01L 23/057

(52) U.S. Cl. CPC H10W 76/60; H10W 76/157

(57) ABSTRACT

The present invention discloses a semiconductor device, which comprises a package shell provided with a first recess, wherein the first recess houses a die and an end surface of a side wall of the first recess extending around an opening of the first recess is formed as a first annular end surface; a plurality of conductive pins disposed on the first annular end surface and spaced apart around the opening of the first recess, wherein an adhesive-dispensing channel is formed between two adjacent conductive pins by spacing apart two adjacent edges thereof; and a cover plate and encapsulant, wherein the cover plate covers the first recess, and the encapsulant is disposed between the conductive pins and the cover plate and within the adhesive-dispensing channel; wherein both ends of the adhesive-dispensing channel in a longitudinal direction thereof are respectively a first adhesive outlet end and a second adhesive outlet end, wherein at least one of the first adhesive outlet end and the second adhesive outlet end is formed as a widened end, wherein the adhesive-dispensing channel has an expansion section corresponding to the widened end, the expansion section being in communication with the corresponding widened end, and in a direction toward the corresponding widened end, the width of the expansion section gradually increases.

### CROSS-REFERENCE TO RELATED APPLICATION

The present disclosure claims priority to Chinese Patent Application No. 202411463135.1 filed on Oct. 18, 2024, the contents of which are herein incorporated by reference in its entirety.

### FIELD

This application relates to the field of semiconductor packaging, and more particularly to a semiconductor device.

### BACKGROUND

Metal-ceramic packaging has good heat dissipation and insulation properties, and is commonly used in manufacturing semiconductor devices. Generally, manufacturing a semiconductor device using metal-ceramic packaging includes a package shell, conductive pins, a die, a cover plate, and encapsulant. The package shell is provided with a first recess, and an end surface of a side wall of the first recess extending around the opening of the first recess is formed as a first annular end surface. A plurality of conductive pins are disposed on the first annular end surface and spaced apart around the opening of the first recess. The die is disposed in the first recess. The cover plate covers the first recess; the encapsulant is disposed between the conductive pins and the cover plate and between the spaced conductive pins.

However, in prior art semiconductor device products fabricated with metal-ceramic packaging, abnormal hermeticity issues are frequently observed during hermeticity testing. Thus, enhancing the hermeticity of semiconductor devices remains a critical technical challenge requiring urgent resolution by those skilled in the art.

### SUMMARY

Some examples described herein may have an object to provide a semiconductor device, which can effectively improve the hermeticity of semiconductor devices.

In some examples, a semiconductor device is provided, comprising:
a package shell provided with a first recess, wherein the first recess houses a die and an end surface of a side wall of the first recess extending around an opening of the first recess is formed as a first annular end surface;
a plurality of conductive pins disposed on the first annular end surface and spaced apart around the opening of the first recess, wherein an adhesive-dispensing channel is formed between two adjacent conductive pins by spacing apart two adjacent edges thereof; and
a cover plate and encapsulant, wherein the cover plate covers the first recess, and the encapsulant is disposed between the conductive pins and the cover plate and within the adhesive-dispensing channel;
wherein both ends of the adhesive-dispensing channel in a longitudinal direction thereof are respectively a first adhesive outlet end and a second adhesive outlet end, wherein at least one of the first adhesive outlet end and the second adhesive outlet end is formed as a widened end, wherein the adhesive-dispensing channel has an expansion section corresponding to the widened end, the expansion section being in communication with the corresponding widened end, and in a direction toward the corresponding widened end, the width of the expansion section gradually increases.

Unlike the prior art, the present application improves the flowability of the encapsulant in the adhesive-dispensing channel during the manufacturing process of the semiconductor device by providing a widened end and a corresponding expansion section in the adhesive-dispensing channel. As a result, the overflow effect of the encapsulant through the adhesive-dispensing channel is improved, so that the encapsulant more fully fills the adhesive-dispensing channel during the overflow process, thereby improving the hermeticity of the semiconductor device.

Details of one or more embodiments of the present application are set forth in the accompanying drawings and the description below. Other features, objects, and advantages of the present application will become apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a schematic cross-sectional structural diagram of a semiconductor device according to Embodiment 1 of the present application.

FIG. 2 is a schematic diagram showing the marking of the first region and the second region in FIG. 1.

FIG. 3 is a schematic diagram of a perspective view of an assembly structure of a package shell, solder pad layer, and conductive pins of a semiconductor device according to Embodiment 1 of the present application.

FIG. 4 is a schematic diagram of another perspective view of an assembly structure of a package shell, solder pad layer, and conductive pins of a semiconductor device according to Embodiment 1 of the present application.

FIG. 5 is an enlarged schematic view of region A in FIG. 4.

FIG. 6 is a schematic diagram marking the region of the adhesive-dispensing channel in FIG. 4, wherein the region of the adhesive-dispensing channel is the hatched area.

FIG. 7 is a schematic diagram marking the region of one expansion section in FIG. 4, wherein the region of the expansion section is the hatched area.

FIG. 8 is a schematic diagram marking the region of another expansion section in FIG. 4, wherein the region of the expansion section is the hatched area.

FIG. 9 is a schematic diagram marking the region of a communication portion in FIG. 4, wherein the region of the communication portion is the hatched area.

FIG. 10 is a schematic diagram marking the first endpoint and the second endpoint in FIG. 4.

FIG. 11 is a schematic diagram showing dimensional annotations of FIG. 4.

FIG. 12 is a schematic partial structural diagram of a semiconductor device according to Embodiment 3 of the present application.

FIG. 13 is a schematic partial structural diagram of a semiconductor device according to Embodiment 4 of the present application.

FIG. 14 is a schematic partial structural diagram of a first semiconductor device.

FIG. 15 is a schematic diagram showing a packaging effect of the first semiconductor device.

FIG. 16 is a schematic diagram showing a packaging effect of a second semiconductor device.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

In order to make the objectives, features, and advantages of the present invention more clearly understood, specific embodiments of the invention are described in detail below with reference to the accompanying drawings.

To facilitate a better understanding of the technical solutions of the invention for those skilled in the art, the following descriptions of the embodiments of the invention are provided clearly and comprehensively with reference to the accompanying drawings. It should be understood that the described embodiments are only part of the invention and not exhaustive. All other embodiments obtained by those skilled in the art without involving inventive activity, based on the disclosed embodiments, shall fall within the scope of protection of the invention.

It should also be noted that the terms “first,” “second,” and so on, used in the specification, claims, and drawings of the invention, are merely to distinguish similar elements and do not imply a particular sequence or order. These terms can be used interchangeably when appropriate, so that the embodiments of the invention can be implemented in sequences other than those illustrated or described. Furthermore, the terms “include”, “comprise” and variations thereof are intended to be non-exclusive. For example, a process, method, system, product, or apparatus that comprises a series of steps or elements is not limited to only those explicitly listed but may also include other steps or elements that are inherent or not expressly stated.

Additionally, it should be noted that the division of embodiments in this disclosure is made for ease of explanation and should not be interpreted as limiting. Features of the various embodiments may be combined or referenced where there is no conflict.

The inventors have found that, in semiconductor devices manufactured using metal-ceramic packaging in the prior art, the sealing performance between adjacent conductive pins is poor, resulting in the frequent detection of abnormal hermeticity during hermeticity testing of the semiconductor devices. To solve the above technical problem, the inventors of the present application propose the following embodiments.

It should be noted that for any numerical values x1 and x2, if x2>x1, then x1˜x2 means not less than x1 and not greater than x2.

### Embodiment 1

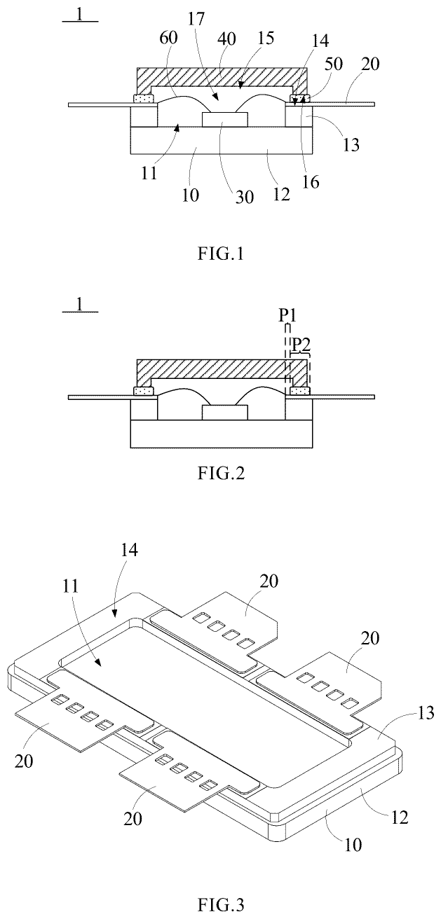

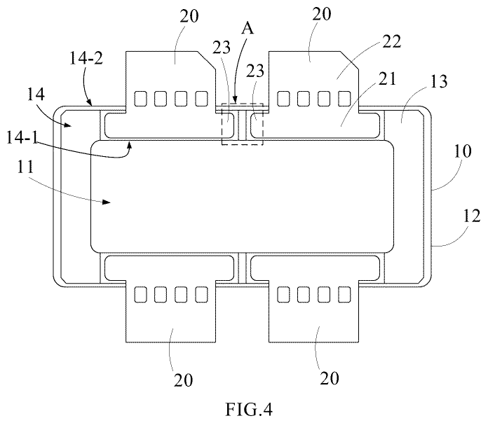

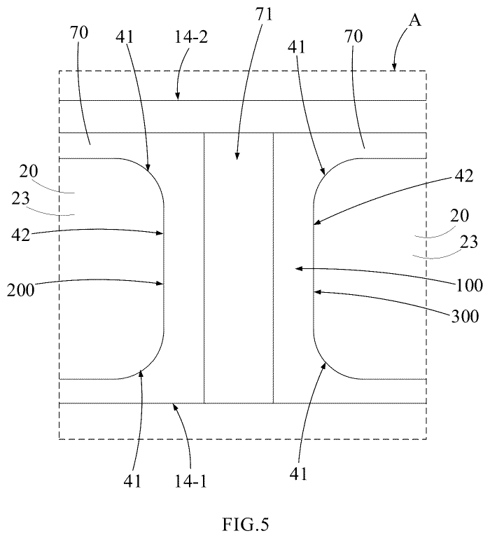

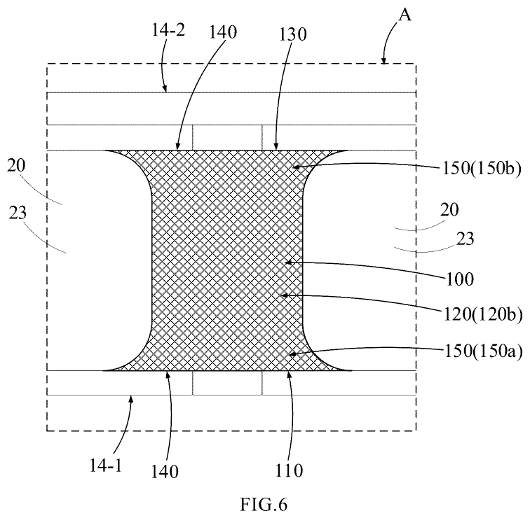

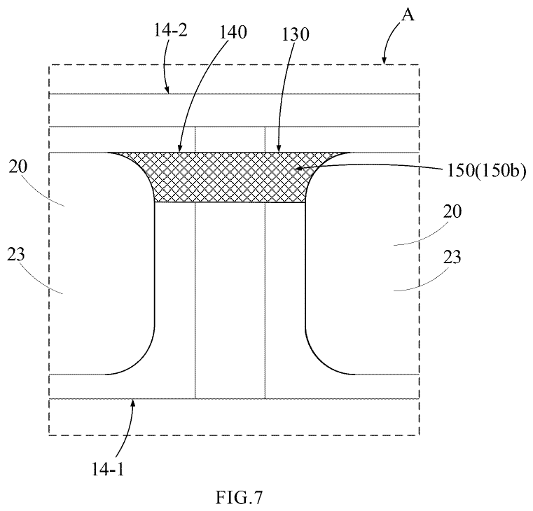

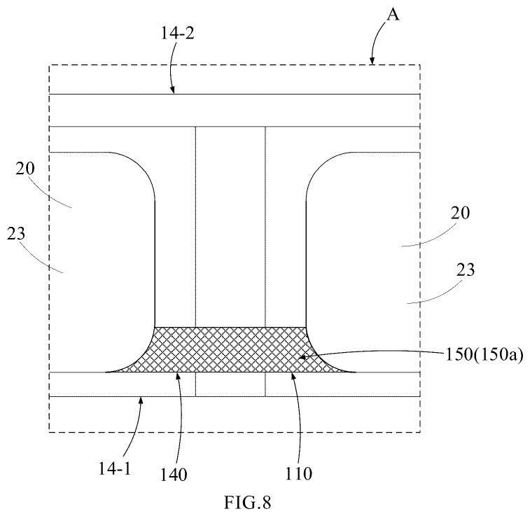

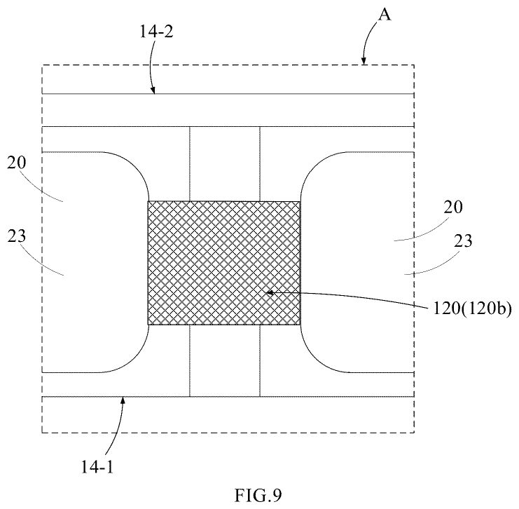

Please refer to FIGS. 1 to 10. The semiconductor device 1 of this embodiment comprises a package shell 10, a die 30, conductive pins 20, a cover plate 40, and an encapsulant 50.

The package shell 10 is provided with a first recess 11, and the first recess 11 houses the die 30. An end surface of a side wall of the first recess 11 extending around an opening of the first recess 11 is formed as a first annular end surface 14. A plurality of conductive pins 20 are disposed on the first annular end surface 14 and spaced apart around the opening of the first recess 11. An adhesive-dispensing channel 100 is formed between two adjacent conductive pins 20 by spacing apart two adjacent edges thereof. The cover plate 40 covers the first recess 11. The encapsulant 50 is disposed between the conductive pins 20 and the cover plate 40 and within the adhesive-dispensing channel 100.

Both ends of the adhesive-dispensing channel 100 in a longitudinal direction thereof are respectively a first adhesive outlet end 110 and a second adhesive outlet end 130. At least one of the first adhesive outlet end 110 and the second adhesive outlet end 130 is formed as a widened end 140. The adhesive-dispensing channel 100 has an expansion section 150 corresponding to the widened end 140, the expansion section 150 being in communication with the corresponding widened end 140. In a direction toward the corresponding widened end 140, the width of the expansion section 150 gradually increases.

In this manner, during the manufacturing process of the semiconductor device 1, when the cover plate 40 is pressed onto the package shell 10, the encapsulant 50 still has fluidity. In this embodiment, the widened end 140 can improve the flowability of the encapsulant 50 in the adhesive-dispensing channel 100, thereby improving the overflow effect of the encapsulant 50 through the adhesive-dispensing channel 100, enabling the encapsulant 50 to more fully fill the adhesive-dispensing channel 100 during the overflow process, and thus improving the hermeticity of the semiconductor device 1.

Optionally, when viewed in plan from the side of the conductive pins 20 opposite to the first annular end surface 14 toward the first annular end surface 14, the annular shape of the first annular end surface 14 may be a rectangular ring, elliptical ring, circular ring, triangular ring, sector-shaped ring, trapezoidal ring, or other regular or irregular ring shape.

For ease of description, the following description takes the case where the annular shape of the first annular end surface 14 is a rectangular ring as an example. In this case, when viewed in plan from the side of the conductive pins 20 opposite to the first annular end surface 14 toward the first recess 11, the opening of the first recess 11 is rectangular. A plurality of conductive pins 20 may be distributed in regions of the first annular end surface 14 located along two pairs of opposite sides of the rectangle of the opening of the first recess 11, but is not limited thereto.

It can be understood that after the encapsulant 50 flows into the adhesive-dispensing channel 100, as the cover plate 40 continues to be pressed toward the package shell 10, the encapsulant 50 between the cover plate 40 and the first annular end surface 14 is compressed, and part of the encapsulant 50 will flow out through the adhesive-dispensing channel 100. In this process, the encapsulant 50 more fully fills the adhesive-dispensing channel 100. It should be noted that in the subsequent process of manufacturing the semiconductor device 1, the fluid encapsulant 50 will solidify to form a non-fluid encapsulant 50, so that the encapsulant 50 in the finally manufactured semiconductor device 1 is the solidified encapsulant 50.

Optionally, as shown in FIGS. 1 to 10, the semiconductor device 1 comprises bonding wires 60. A side of the cover plate 40 facing the first recess 11 is provided with a second recess 15, and an end surface of a side wall of the second recess 15 extending around an opening of the second recess 15 is formed as a second annular end surface 16.

The first annular end surface 14 has an inner annular edge 14-1 close to the first recess 11 and an outer annular edge 14-2 away from the first recess 11. A portion of the conductive pin 20 covering the first annular end surface 14 has a first region P1 close to the inner annular edge 14-1 and a second region P2 away from the inner annular edge 14-1. The second recess 15 communicates with the first recess 11 to form a cavity 17. The second annular end surface 16 is disposed corresponding to the first annular end surface 14 and covers the second region P2 of the conductive pin 20, and the first region P1 of the conductive pin 20 is located within the cavity 17. The die 30 is connected to the first region P1 of the conductive pin 20 via the bonding wires 60.

In this manner, the bonding wires 60, the die 30, and the first region P1 of the conductive pins 20 are all located within the cavity. The position between the first annular end surface 14 and the second annular end surface 16 is sealed by the encapsulant 50 between the second region P2 of the conductive pin 20 and the second annular end surface 16 and by the encapsulant 50 in the adhesive-dispensing channel 100. Thus, when the cover plate 40 is pressed onto the package shell 10, the second annular end surface 16 can avoid the bonding wires 60, thereby preventing the bonding wires 60 from being pressed and broken by the second annular end surface 16.

It should be noted that, in the manufacturing process of the semiconductor device 1, before pressing the cover plate 40 onto the package shell 10, the encapsulant 50 is disposed continuously in an annular distribution manner on the second annular end surface 16 of the cover plate 40. When the cover plate 40 is pressed onto the package shell 10, the encapsulant 50 distributed on the second annular end surface 16 contacts the second region P2 and avoids the first region P1.

By way of example and not limitation, as shown in FIGS. 1 to 11, the width of the widened end 140 is the second width w2, and the second width w2 is 0.5 to 5 mm.

It should be noted that, by means of the above arrangement, at least the following two advantageous effects are obtained. First, since the second width is not greater than 5 mm, after the second region P2 of the connection portion 21 contacts the encapsulant 50, the connection portion 21 still has a sufficient first region P1 for bonding with the bonding wires 60. Second, since the second width is not less than 0.5 mm, during the manufacturing process of the semiconductor device 1, when the cover plate 40 is pressed onto the package shell 10, the encapsulant 50 in the adhesive-dispensing channel 100 more easily flows out through the corresponding widened end 140 under the guidance of the expansion section 150, enabling the adhesive-dispensing channel to be fully filled with encapsulant 50, thereby providing better sealing performance after the encapsulant 50 solidifies. Preferably, the second width w2 is 1 to 2 mm.

Optionally, the die 30 includes, but is not limited to, active elements or passive elements. The active elements include, but are not limited to, one or more of transistors, microprocessors, memory devices, and RF chips. The passive elements include, but are not limited to, one or more of capacitors, inductors, and resistors.

Optionally, as shown in FIGS. 1 to 10, two adjacent conductive pins 20 have adjacent edges respectively serving as a first edge 200 and a second edge 300.

The first edge 200 and the second edge 300 are each formed with an expansion edge 41, wherein the edges on both sides of the expansion section 150 along the width direction of the adhesive-dispensing channel 100 are formed by the expansion edge 41 of one of the first edge 200 and the second edge 300. In this way, during the manufacturing process of the semiconductor device 1, the encapsulant 50 flowing into the adhesive-dispensing channel 100 can be guided along the expansion edge 41 to adapt to the change in the width of the expansion section 150 and fill the expansion section 150.

Optionally, as shown in FIGS. 1 to 10, the expansion edge 41 includes any one or a combination of an oblique edge and a curved edge, so that in a direction toward the corresponding widened end 140, the width of the expansion section 150 gradually increases.

By way of example and not limitation, in a first example, the expansion edge 41 may be an oblique edge. In a second example, the expansion edge 41 may be a curved edge. Optionally, in the second example, the curved edge serving as the expansion edge 41 may be an arc edge. Optionally, in the second example, the curved edge serving as the expansion edge 41 may be another curved edge that is non-arc. In a third example, the expansion edge 41 may be a combination of an oblique edge and a curved edge.

Optionally, as shown in FIGS. 1 to 11, the length of the adhesive-dispensing channel 100 is the first length s1, and the first length s1 is 1 mm to 2 mm. By way of example and not limitation, the first length s1 includes, but is not limited to, 1.00 mm, 1.50 mm, or 2.00 mm.

It should be noted that, by means of the above arrangement, at least the following two advantageous effects are obtained. First, since the first length s1 is not greater than 2 mm, the volume of encapsulant 50 required to fill the adhesive-dispensing channel 100 is reduced. This can reduce the amount of encapsulant 50 used, and the reduction in the amount of encapsulant 50 is conducive to lowering the difficulty of the packaging process. Second, since the first length s1 is not less than 1 mm, after the second region P2 of the connection portion 21 contacts the encapsulant 50, the connection portion 21 still has a sufficient first region P1 for bonding with the bonding wires 60.

Furthermore, the first length s1 is 1.25 to 1.45 mm. By way of example and not limitation, the first length s1 includes, but is not limited to, 1.25 mm, 1.35 mm, or 1.45 mm.

As shown in FIGS. 1 to 11, from one end of the expansion section 150 remote from the corresponding widened end 140 to one end of the expansion section 150 close to the corresponding widened end 140, the expansion edge 41 sequentially connects a first endpoint B1 and a second endpoint B2.

The distance between the first endpoint B1 and the second endpoint B2 along the width direction of the adhesive-dispensing channel 100 is a first distance d1, and the first distance d1 is not greater than 1 mm. This configuration may offer two advantages: first, the volume of encapsulant 50 required to fill the adhesive-dispensing channel 100 is reduced. This can reduce the amount of encapsulant 50 used, and the reduction in the amount of encapsulant 50 is conducive to lowering the difficulty of the packaging process. Second, after the second region P2 of the connection portion 21 contacts the encapsulant 50, the connection portion 21 still has a sufficient first region P1 for bonding with the bonding wires 60.

Optionally, as shown in FIGS. 1 to 11, the length d2 of the expansion section 150 is a distance between the first endpoint B1 and the second endpoint B2 along the length direction of the adhesive-dispensing channel 100. The ratio of the first distance d1 to the length d2 of the expansion section 150 is a second ratio, and the second ratio is 1:3-2:1.

It should be noted that, considering the limited first length s1 of the adhesive-dispensing channel 100, if the second ratio is too large, the first distance d1 is likely to become too small, making it difficult for the encapsulant 50 in the adhesive-dispensing channel 100 to flow out of the widened end 140. Preferably, the second ratio is 1:2-1:1. More preferably, the second ratio is 1:2-1:1.1. For example, the second ratio includes, but is not limited to, 1:1.2.

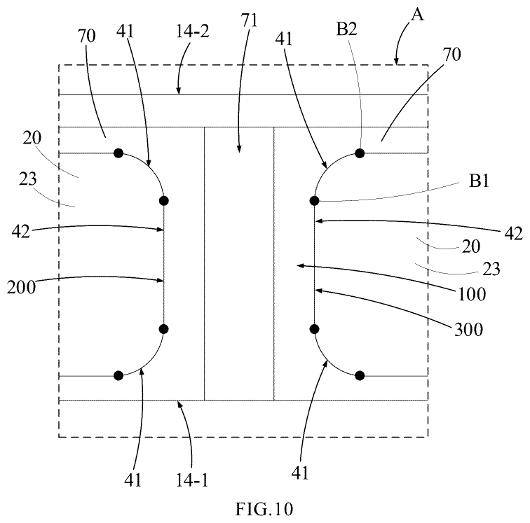

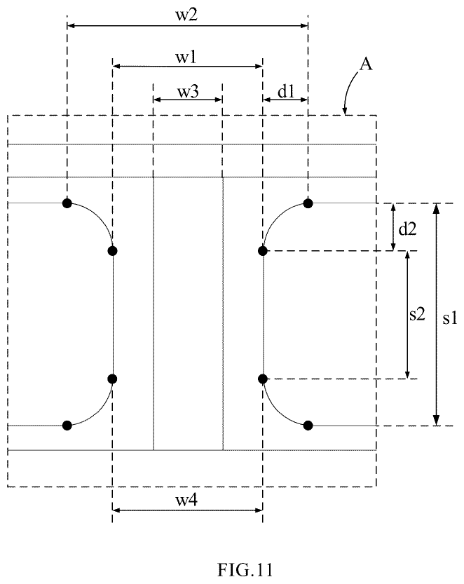

Optionally, in combination with FIGS. 1 to 9 and referring to FIGS. 10 to 11, the ratio of the length d2 of the expansion section 150 to the first length s1 is a first ratio, and the first ratio is not less than 0.2. By means of the above arrangement, since the first ratio is not less than 0.2, given the limited first length s1 of the adhesive-dispensing channel 100, the expansion section 150 has a sufficient length to facilitate the outflow of encapsulant 50 from the widened end 140 when the cover plate 40 is pressed onto the package shell 10 during the manufacturing process of the semiconductor device 1.

Optionally, in combination with FIGS. 1 to 9 and referring to FIGS. 10 to 11, the width at one end of the expansion section 150 remote from the corresponding widened end 140 is the first width w1, and the first width w1 is not less than 0.1 mm. It should be noted that if the first width w1 is less than 0.1 mm, during the manufacturing process of the semiconductor device 1, when the cover plate 40 is pressed onto the package shell 10, the flow of the encapsulant 50 is hindered.

Optionally, in combination with FIGS. 1 to 9 and referring to FIGS. 10 to 11, the first width w1 is not greater than 2 mm. This avoids an increase in the usage of encapsulant 50 required to fill the adhesive-dispensing channel 100, thereby reducing the amount of encapsulant 50 sandwiched between the second annular end surface 16 and the first annular end surface 14 during the manufacturing process of the semiconductor device 1 when pressing the cover plate 40 onto the package shell 10, and thus reducing the difficulty of the packaging process.

Preferably, the first width w1 may be 0.3 mm to 2 mm.

Optionally, in order to allow more conductive pins 20 to be disposed on the first annular end surface 14 or to miniaturize the semiconductor device 1, the first width w1 may be 0.3 mm to 0.5 mm.

Optionally, as shown in FIGS. 1 to 10, the conductive pin 20 comprises a connection portion 21 and an extension portion 22. The connection portion 21 is disposed on the first annular end surface 14, and the extension portion 22 extends from the connection portion 21 to a side of the outer annular edge 14-2 away from the inner annular edge 14-1.

The first region P1 and the second region P2 are located on the connection portion 21. Both ends of the connection portion 21 in a circumferential direction around the first recess 11 are respectively formed as protruding ends 23 projecting relative to the extension portion 22 in the circumferential direction around the first recess 11. Two opposing edges of the protruding ends 23 of two adjacent conductive pins 20 constitute the adhesive-dispensing channel 100.

By means of the above arrangement, forming the adhesive-dispensing channel 100 between the opposing edges of the protruding ends 23 of two adjacent conductive pins 20 can greatly reduce the length of the adhesive-dispensing channel 100, thereby facilitating improvement of the flowability of the encapsulant 50 in the adhesive-dispensing channel 100 during the manufacturing process of the semiconductor device 1. Moreover, the protruding ends 23 increase the overall length of the connection portion 21 in the circumferential direction around the first recess 11, so that the first region P1 of the connection portion 21 has a sufficient length for bonding with the bonding wires 60, thereby increasing the area of the conductive pins 20 that can be used for bonding with the bonding wires 60.

Optionally, as shown in FIGS. 1 to 10, the package shell 10 comprises a heat sink plate 12 and a ceramic insulating ring 13, the ceramic insulating ring 13 being disposed on the heat sink plate 12 to enclose the first recess 11. The first annular end surface 14 is an end surface of the ceramic insulating ring 13 extending around the opening of the first recess 11.

The package shell 10 assembly comprises a solder pad layer 70, with the solder pad layer 70 provided between each conductive pin 20 and the first annular end surface 14. In this way, first, soldering the conductive pins 20 to the ceramic insulating ring 13 via the solder pad layer 70 can enhance the connection strength between the conductive pins 20 and the ceramic insulating ring 13. Second, the heat sink plate 12 can promptly conduct heat from the die 30 and dissipate the heat to the outside of the semiconductor device 1.

Optionally, the solder pad layer 70 includes, but is not limited to, a molybdenum layer.

Optionally, as shown in FIGS. 1 to 11, solder pad layers 70 below two adjacent conductive pins 20 are spaced apart to form a first gap 71, and a side of the first gap 71 away from the first annular end surface 14 is in communication with the adhesive-dispensing channel 100. The width of the first gap 71 is a third width w3, and the third width w3 is not greater than the first width w1. Preferably, the third width w3 is less than the first width w1, and the first width w1 is less than the second width w2.

Optionally, as shown in FIGS. 1 to 11, the third width w3 may be 0.1 mm to 2 mm. Preferably, the third width w3 may be 0.3 mm to 0.5 mm. This not only allows adjacent solder pad layers 70 to be insulated from each other, but also facilitates filling the first gap 71 with encapsulant 50. By way of example and not limitation, the third width w3 includes, but is not limited to, 0.3 mm, 0.4 mm, or 0.5 mm.

### Embodiment 2

Referring to FIGS. 1 to 11, Embodiment 2 is obtained by further defining Embodiment 1. Descriptions identical to those in Embodiment 1 will not be repeated, and the further limitations of Embodiment 2 compared with Embodiment 1 are as follows.

Optionally, as shown in FIGS. 1 to 11, the adhesive-dispensing channel 100 is formed with a communication portion 120, and one end of the expansion section 150 remote from the corresponding widened end 140 is in communication with the communication portion 120. A width of the communication portion 120 is a fourth width w4, and a width of the widened end 140 is a second width w2, wherein the fourth width w4 is less than the second width w2.

In this way, during the manufacturing process of the semiconductor device 1, as the cover plate 40 is pressed onto the package shell 10, the fluid encapsulant 50 is compressed, causing the encapsulant 50 to continuously flow into the adhesive-dispensing channel 100. As the encapsulant 50 continues to flow into the adhesive-dispensing channel 100, under the guidance of the expansion edge 41, the encapsulant 50 in the adhesive-dispensing channel 100 flows from the communication portion 120 toward the widened end 140, thereby enabling the encapsulant 50 to more fully fill the communication portion 120, the expansion section 150, and the widened end 140.

Optionally, as shown in FIGS. 1 to 11, the fourth width w4 is equal to the first width w1. In this way, during the manufacturing process of the semiconductor device 1, as the cover plate 40 is pressed onto the package shell 10, the encapsulant 50 can smoothly transition from the communication portion 120 to the expansion section 150.

Optionally, as shown in FIGS. 1 to 11, the first adhesive outlet end 110 faces the inner annular edge, and the second adhesive outlet end 130 faces the outer annular edge. Both the first adhesive outlet end 110 and the second adhesive outlet end 130 are formed as widened ends 140. The expansion section 150 corresponding to the widened end 140 of the first adhesive outlet end 110 is a first expansion section 150a. The expansion section 150 corresponding to the widened end 140 of the second adhesive outlet end 130 is a second expansion section 150b. The first expansion section 150a and the second expansion section 150b are spaced apart, with the communication portion 120 located between the first expansion section 150a and the second expansion section 150b. The communication portion 120 is formed as a communication section 120b, and the communication section 120b is respectively in communication with the first expansion section 150a and the second expansion section 150b.

In this way, both the first adhesive outlet end 110 and the second adhesive outlet end 130 are formed as widened ends 140, so that during the manufacturing process of the semiconductor device 1, as the encapsulant 50 continuously flows into the adhesive-dispensing channel 100, the encapsulant 50 in the adhesive-dispensing channel 100 can achieve both first flow and second flow. The first flow includes flowing from the communication section 120b to the first adhesive outlet end 110 under the guidance of the expansion edge 41 of the first expansion section 150a. The second flow includes flowing from the communication section 120b to the second adhesive outlet end 130 under the guidance of the expansion edge 41 of the second expansion section 150b. This enables the encapsulant 50 to more fully fill the communication section 120b, the first expansion section 150a, the widened end 140 of the first adhesive outlet end 110, the second expansion section 150b, and the widened end 140 of the second adhesive outlet end 130.

It should be noted that the width of the communication portion 120 is the width of the communication section 120b, i.e., the width of the communication section 120b is the fourth width w4.

Optionally, as shown in FIGS. 1 to 11, both the first edge 200 and the second edge 300 are formed with a transition edge 42. The edges on both sides of the communication section 120b along the width direction of the adhesive-dispensing channel 100 are formed by the transition edge 42 of one of the first edge 200 and the second edge 300. The transition edge 42 of the first edge 200 and the transition edge 42 of the second edge 300 may be arranged in parallel.

In this way, since the transition edge 42 of the first edge 200 and the transition edge 42 of the second edge 300 are arranged in parallel, the width of the communication section 120b remains the same at all points along the length direction of the adhesive-dispensing channel 100, thereby enabling the encapsulant 50 flowing into the communication section 120b to be more evenly diverted to achieve the first flow and the second flow. The first flow includes flowing from the communication section 120b to the first adhesive outlet end 110 under the guidance of the expansion edge 41 of the first expansion section 150a. The second flow includes flowing from the communication section 120b to the second adhesive outlet end 130 under the guidance of the expansion edge 41 of the second expansion section 150b.

Optionally, as shown in FIGS. 1 to 11, in order to facilitate the flow of the encapsulant 50 in the adhesive-dispensing channel 100, in either one of the first edge 200 or the second edge 300, the expansion edge 41 smoothly transitions into the transition edge 42.

### Embodiment 3

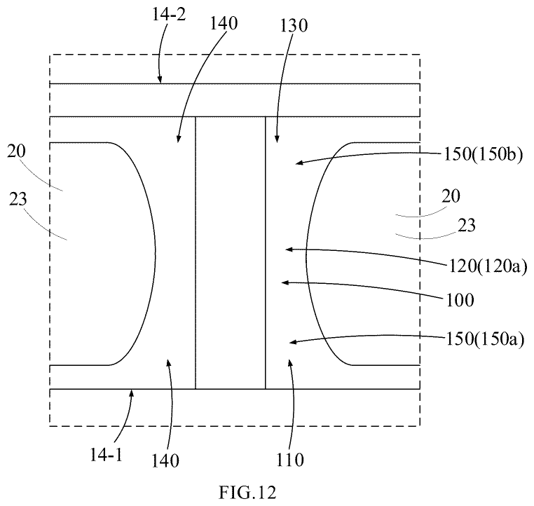

Comparing FIGS. 1 to 11 and referring to FIG. 12, Embodiment 3 is a modification derived from Embodiment 2. Descriptions identical to those in Embodiment 2 will not be repeated, and the differences between Embodiment 3 and Embodiment 2 are as follows.

Optionally, comparing FIGS. 1 to 11 and referring to FIG. 12, the first expansion section 150a and the second expansion section 150b are directly connected, with the communication portion 120 located between the first expansion section 150a and the second expansion section 150b, and the communication portion 120 being formed as a communication port 120a at the junction of the first expansion section 150a and the second expansion section 150b. The communication port 120a is in communication with both the first expansion section 150a and the second expansion section 150b.

It should be noted that the width of the communication portion 120 is the width of the communication port 120a, i.e., the width of the communication port 120a is the fourth width w4.

### Embodiment 4

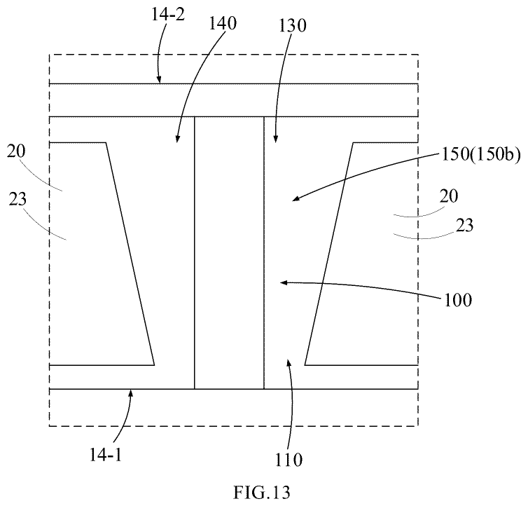

Comparing FIGS. 1 to 11 and referring to FIG. 13, Embodiment 4 is a modification derived from Embodiment 1. Descriptions identical to those in Embodiment 1 will not be repeated, and the differences between Embodiment 4 and Embodiment 1 are as follows.

The first adhesive outlet end 110 faces the inner annular edge 14-1, and the second adhesive outlet end 130 faces the outer annular edge 14-2. The first adhesive outlet end 110 is not formed as a widened end 140, and the second adhesive outlet end 130 is formed as a widened end 140.

In this way, during the manufacturing process of the semiconductor device 1, when the cover plate 40 is pressed onto the package shell 10, under the guidance of the expansion section 150 corresponding to the widened end 140 of the second adhesive outlet end 130, the proportion of fluid encapsulant 50 in the adhesive-dispensing channel 100 that is diverted to achieve a third flow is reduced, and the proportion of fluid encapsulant 50 that is diverted to achieve a fourth flow is increased. The third flow includes flowing toward the first adhesive outlet end 110. The fourth flow includes flowing toward the second adhesive outlet end 130. Thus, during the manufacturing process of the semiconductor device 1, when the cover plate 40 is pressed onto the package shell 10, the proportion of encapsulant 50 in the adhesive-dispensing channel 100 flowing into the first recess 11 is reduced, and the proportion flowing out from the second adhesive outlet end 130 is increased, thereby enhancing the filling and sealing effect of the encapsulant 50 for the expansion section 150 corresponding to the widened end 140 of the second adhesive outlet end 130 and for the widened end 140 of the second adhesive outlet end 130.

Optionally, comparing FIGS. 1 to 11 and referring to FIG. 13, the expansion section 150 corresponding to the widened end 140 of the second adhesive outlet end 130 is the second expansion section 150b. In a direction toward the widened end 140 of the second adhesive outlet end 130, the second expansion section 150b extends from the first adhesive outlet end 110 to the second adhesive outlet end 130. In this way, the filling and sealing effect of the encapsulant 50 for the second expansion section 150b and the widened end 140 of the second adhesive outlet end 130 can be greatly enhanced.

### Comparative Experiment

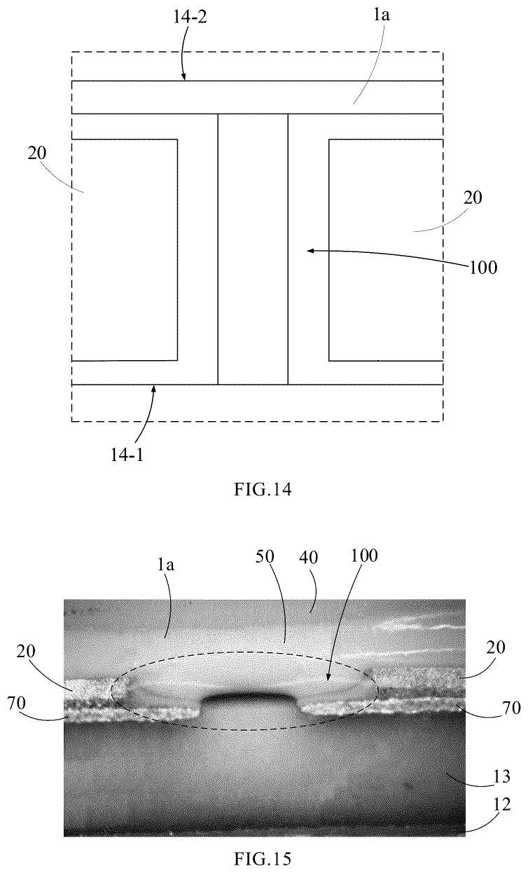

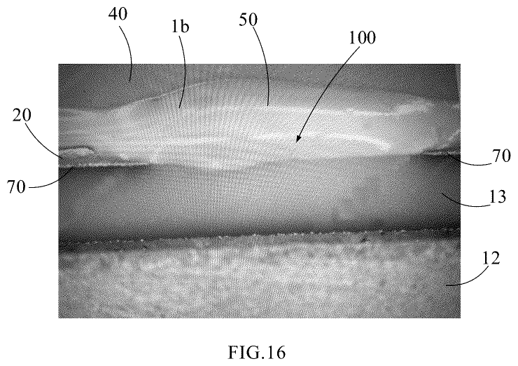

A first semiconductor device 1a and a second semiconductor device 1b are taken, wherein the first semiconductor device 1a is a semiconductor device in the prior art, and the second semiconductor device 1b is the semiconductor device 1 described above in this embodiment. For example, the second semiconductor device 1b may be the semiconductor device 1 described above in Embodiment 2. Similarities between the first semiconductor device 1a and the second semiconductor device 1b will not be repeated. The difference between the first semiconductor device 1a and the second semiconductor device 1b is that, comparing FIGS. 5 to 9 and referring to FIG. 14, the adhesive-dispensing channel 100 of the first semiconductor device 1a is not formed with a widened end 140. The first semiconductor device 1a and the second semiconductor device 1b are respectively observed from the side to obtain FIGS. 15 and 16.

As shown in FIG. 15, the encapsulant 50 in the adhesive-dispensing channel 100 of the first semiconductor device 1a has a distinct layered structure with the ceramic insulating ring 13, with the layering indicated by the dashed circle in FIG. 15. Along both sides of the adhesive-dispensing channel 100 in the width direction thereof, the first semiconductor device 1a has distinct unfilled portions, which are indicated by the dashed circle in FIG. 15. As shown in FIG. 16, the encapsulant 50 in the adhesive-dispensing channel 100 of the second semiconductor device 1b has no distinct layering with the ceramic insulating ring 13, and no obvious unfilled portions are present along both sides of the adhesive-dispensing channel 100 in the width direction thereof.

Clearly, the widened end 140 of the semiconductor device 1 of the present embodiment can improve the flowability of the encapsulant 50, thereby improving the overflow effect of the encapsulant 50 through the adhesive-dispensing channel 100, enabling the encapsulant 50 to more fully fill the adhesive-dispensing channel 100 during the overflow process, and thereby improving the hermeticity of the semiconductor device 1.

The above is merely an embodiment of the present invention, and is not intended to limit the scope of the present invention. Any equivalent structural or process modifications made based on the contents of the description and drawings of the present embodiment, or any direct or indirect applications in other related technical fields, shall be deemed to be included within the scope of protection of the present invention.

What is claimed is:

1. A semiconductor device, comprising:
a package shell provided with a first recess, wherein the first recess houses a die and an end surface of a side wall of the first recess extending around an opening of the first recess is formed as a first annular end surface;
a plurality of conductive pins disposed on the first annular end surface and spaced apart around the opening of the first recess, wherein an adhesive-dispensing channel is formed between two adjacent conductive pins by spacing apart two adjacent edges thereof; and
a cover plate and encapsulant, wherein the cover plate covers the first recess, and the encapsulant is disposed between the conductive pins and the cover plate and within the adhesive-dispensing channel;
wherein both ends of the adhesive-dispensing channel in a longitudinal direction thereof are respectively a first adhesive outlet end and a second adhesive outlet end, wherein at least one of the first adhesive outlet end and the second adhesive outlet end is formed as a widened end, wherein the adhesive-dispensing channel has an expansion section corresponding to the widened end, the expansion section being in communication with the corresponding widened end, and in a direction toward the corresponding widened end, the width of the expansion section gradually increases.

2. The semiconductor device according to claim 1, wherein the adhesive-dispensing channel has a first length, a ratio of a length of the expansion section to the first length is a first ratio, and the first ratio is not less than 0.2.

3. The semiconductor device according to claim 2, wherein the first length ranges from 1 mm to 2 mm.

4. The semiconductor device according to claim 1, wherein a width at one end of the expansion section remote from the corresponding widened end is a first width, and the first width is not less than 0.1 mm.

5. The semiconductor device according to claim 4, wherein the first width is not greater than 2 mm.

6. The semiconductor device according to claim 5, wherein the widened end has a width ranging from 0.5 mm to 5 mm.

7. The semiconductor device according to claim 1, wherein the first annular end surface has an inner annular edge close to the first recess and an outer annular edge away from the first recess; the first adhesive outlet end faces the inner annular edge, and the second adhesive outlet end faces the outer annular edge; wherein the first adhesive outlet end is not formed as the widened end, and the second adhesive outlet end is formed as the widened end.

8. The semiconductor device according to claim 7, wherein the expansion section corresponding to the widened end of the second adhesive outlet end is defined as a second expansion section; in a direction toward the widened end of the second adhesive outlet end, the second expansion section extends from the first adhesive outlet end to the second adhesive outlet end.

9. The semiconductor device according to claim 1, wherein the first annular end surface has an inner annular edge close to the first recess and an outer annular edge away from the first recess, wherein the first adhesive outlet end faces the inner annular edge, and the second adhesive outlet end faces the outer annular edge;
wherein both the first adhesive outlet end and the second adhesive outlet end are formed as widened ends, the expansion section corresponding to the widened end of the first adhesive outlet end is defined as a first expansion section, the expansion section corresponding to the widened end of the second adhesive outlet end is defined as a second expansion section, wherein the first expansion section and the second expansion section are directly connected so that a communication port is formed at a junction between the first expansion section and the second expansion section in the adhesive-dispensing channel, the communication port respectively communicating with the first expansion section and the second expansion section.

10. The semiconductor device according to claim 1, wherein the adhesive-dispensing channel is formed with a communication section, in communication with one end of the expansion section remote from the corresponding widened end, and the communication section has a width less than that of the widened end.

11. The semiconductor device according to claim 10, wherein the first annular end surface has an inner annular edge close to the first recess and an outer annular edge away from the first recess, the first and second adhesive outlet ends facing the inner annular edge and the outer annular edge, respectively, and both being formed as widened ends; the expansion section corresponding to the widened end of the first adhesive outlet end is defined as a first expansion section, and the expansion section corresponding to the widened end of the second adhesive outlet end is defined as a second expansion section; and the communication section being located between and communicating with both the first expansion section and the second expansion section, which are spaced apart.

12. The semiconductor device according to claim 1, wherein two adjacent conductive pins have two adjacent edges respectively defined as a first edge and a second edge, and the first edge and the second edge are each formed with an expansion edge, wherein the edges on opposite sides of the expansion section along the width direction of the adhesive-dispensing channel are formed by the expansion edge of one of the first edge and the second edge; the expansion edge comprises any one or a combination of an oblique edge and a curved edge so that in a direction toward the corresponding widened end, the width of the expansion section gradually increases.

13. The semiconductor device according to claim 12, wherein the adhesive-dispensing channel is formed with a communication section, with one end of the expansion section remote from the corresponding widened end being in communication with the communication section, wherein the communication section has a width smaller than that of the widened end, and each of the first edge and the second edge is formed with a transition edge, wherein the transition edges respectively form opposite sides of the communication section along a width direction of the adhesive-dispensing channel and are arranged in parallel.

14. The semiconductor device according to claim 13, wherein in either the first edge or the second edge, the expansion edge smoothly transitions into the transition edge.

15. The semiconductor device according to claim 12, wherein the expansion edge sequentially connects a first endpoint and a second endpoint from one end of the expansion section remote from the corresponding widened end to one end of the expansion section close to the corresponding widened end, and a distance between the first endpoint and the second endpoint along a width direction of the adhesive-dispensing channel is not greater than 1 mm.

16. The semiconductor device according to claim 12, wherein the expansion edge sequentially connects a first endpoint and a second endpoint from one end of the expansion section remote from the corresponding widened end to one end of the expansion section close to the corresponding widened end, and wherein a distance between the first endpoint and the second endpoint along the width direction of the adhesive-dispensing channel is defined as a first distance, a distance between the first endpoint and the second endpoint along a length direction of the adhesive-dispensing channel is defined as a length of the expansion section, and a ratio of the first distance to the length of the expansion section is from 1:3 to 2:1.

17. The semiconductor device according to claim 1, further comprises bonding wires, wherein the cover plate has a second recess on its side facing the first recess, the second recess communicates with the first recess to form a cavity; and a second annular end surface is defined by an end surface of a side wall of the second recess extending around an opening thereof, wherein the first annular end surface has an inner annular edge close to the first recess and an outer annular edge away from the first recess;
wherein a portion of the conductive pin overlying the first annular end surface has a first region close to the inner annular edge and a second region away from the inner annular edge, and the second annular end surface is disposed corresponding to the first annular end surface and covers the second region of the conductive pin, the first region of the conductive pin being located within the cavity; and
wherein the die is bonded to the first region of the conductive pin via the bonding wires.

18. The semiconductor device according to claim 17, wherein the conductive pin includes a connection portion disposed on the first annular end surface and an extension portion extending from the connection portion, wherein the connection portion is formed with a protruding end projecting relative to the extension portion in a circumferential direction around the first recess, and wherein two opposing edges of the protruding ends of two adjacent conductive pins define the adhesive-dispensing channel.

19. The semiconductor device according to claim 1, wherein the package shell includes a heat sink plate and a ceramic insulating ring, the ceramic insulating ring being disposed on the heat sink plate to form the first recess, and the first annular end surface is an end surface of the ceramic insulating ring extending around the opening of the first recess;
wherein the package shell further includes a solder pad layer provided between each conductive pin and the first annular end surface, and adjacent solder pad layers are spaced apart to form a first gap that opens toward the adhesive-dispensing channel on a side facing away from the first annular end surface.

20. The semiconductor device according to claim 19, wherein the first gap has a width of 0.1 mm to 2 mm, which is not greater than a width at one end of the expansion section remote from the corresponding widened end.
